(19) United States
(12) Patent Application Publication
(10) Pub. No.: US 2007/0086230 A1
(43) Pub. Date: Apr. 19, 2007

(54) Nonvolatile latch circuit and system on chip with the same

(75) Inventors: Hee Bok Kang, Cheongju-si (KR); Jin Hong Ahn, Anyang-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/482,069

(22) Filed: Jul. 7, 2006

(30) Foreign Application Priority Data
Oct. 13, 2005 (KR) 10-2005-0096566
Oct. 13, 2005 (KR) 10-2005-0096569

(51) Int. Cl. G11C 11/22

(52) U.S. Cl. 365/145

(57) ABSTRACT

A nonvolatile ferroelectric memory device includes a bottom word line, an insulating layer formed on the bottom word line, a bit line including a floating channel region formed on the insulating layer, a tunnel oxide film formed on the floating channel region, a ferroelectric layer formed on the tunnel oxide film, wherein a change in a polarity of the ferroelectric layer induces a change in a resistance of the floating channel region, and a top word line formed on the ferroelectric layer in parallel with the bottom word line.

### RELATED APPLICATIONS

This application is based upon and claims the benefit of priority to Korean Application No. KR10-2005-0096566 and Korean Application No. KR10-2005-0096569, both filed on Oct. 13, 2005, the entire contents of which are incorporated herein by reference.

### BACKGROUND

1. Technical Field

The present invention generally relates to a nonvolatile ferroelectric memory device, and more specifically, to a technology of controlling a read operation of a nonvolatile memory cell using a channel resistance of the memory cell which changes a polarization state of a nano-scaled ferroelectric material.

2. Description of the Related Art

Generally, a ferroelectric random access memory (hereinafter, referred to as ‘FeRAM’) has attracted considerable attention as next generation memory device because it has a data processing speed as fast as a Dynamic Random Access Memory (hereinafter, referred to as ‘DRAM’) and preserves data even after the power is turned off.

A FeRAM having a structure similar to a DRAM includes capacitors made of a ferroelectric substance, so that it utilizes the high residual polarization characteristic of the ferroelectric substance in which data is not deleted even after an electric field is eliminated.

A unit cell of a conventional nonvolatile FeRAM device includes a switching element and a nonvolatile ferroelectric capacitor. The switching element performs a switching operation depending on a state of a word line to connect a nonvolatile ferroelectric capacitor to a bit line or disconnect the nonvolatile ferroelectric capacitor from the bit line. The nonvolatile ferroelectric capacitor is connected between a plate line and one terminal of the switching element. Here, the switching element of the conventional FeRAM is an NMOS transistor whose switching operation is controlled by a gate control signal.

FIG. 1 is a cross-sectional view illustrating a conventional nonvolatile ferroelectric memory device.

A conventional 1-T (One-Transistor) FET (Field Effect Transistor) cell includes an n-type drain 2 and an n-type source 3 which are formed in a p-type substrate 1. Also, the cell includes an insulation oxide 4, a ferroelectric layer 5, and a word line 6 which are sequentially formed on a channel region between the drain 2 and the source 3.

The above-described conventional nonvolatile FeRAM device reads and writes data by using a channel resistance of the memory cell which changes with a polarization states of the ferroelectric layer 5.

Specifically, the channel region has a high resistance when the polarity of the ferroelectric layer 5 induces positive charges to the channel, and has a low resistance when the polarity of the ferroelectric layer 5 induces negative charges to the channel.

However, in the conventional nonvolatile FeRAM device, when the cell is scaled down, a data retention characteristic is degraded, especially if a nonvolatile ferroelectric memory cell has a nanometer scale. For example, in a read mode, a read voltage may appear at adjacent cells to generate crosstalk noise that destroys data. In a write mode, a write voltage may appear at an unselected cell to destroy data of unselected cells. As a result, it is difficult to perform a random access operation.

Also, the retention characteristic is degraded by depolarization charges in case of a conventional MFIS (Metal Ferroelectric Insulator Silicon) or MFMIS (Metal Ferroelectric Metal Insulator Silicon). For example, when there is an insulation oxide 4 between the ferroelectric layer 5 and the channel region, the depolarization charges are accumulated between the ferroelectric layer 5 and the insulation oxide 4 to degrade the retention characteristic of the MFIS. Similarly, when there is a metal insulating layer between the ferroelectric layer 5 and the channel region, the depolarization charges are accumulated between the ferroelectric layer 5 and the metal to degrade the retention of the MFMIS.

### SUMMARY

Various embodiments of the present invention are directed at providing a nonvolatile ferroelectric memory device including a floating channel layer between a top word line and a bottom word line to improve reliability of cells.

Various embodiments of the present invention are directed at providing a nonvolatile ferroelectric memory device including a nano-scaled floating channel layer between a top word line and a bottom word line.

Various embodiments of the present invention are directed at providing a nonvolatile ferroelectric memory device including a tunnel oxide film between a ferroelectric layer and a channel region to prevent diffusion of impurities of the ferroelectric layer into the channel region.

Various embodiments of the present invention are directed at providing a nonvolatile ferroelectric memory device including a tunnel oxide film between a ferroelectric layer and a channel region to improve a retention characteristic of the ferroelectric layer.

Consistent with the present invention, a nonvolatile ferroelectric memory device includes a bottom word line, an insulating layer formed on the bottom word line, a bit line including a floating channel region formed on the insulating layer, a tunnel oxide film formed on the floating channel region, a ferroelectric layer formed on the tunnel oxide film, wherein a change in a polarity of the ferroelectric layer induces a change in a resistance of the floating channel region, and a top word line formed on the ferroelectric layer in parallel with the bottom word line.

Consistent with the present invention, a nonvolatile ferroelectric memory device includes a plurality of unit cells arranged in a plurality of layers. Each of the unit cells includes a bottom word line; an insulating layer formed on the bottom word line; a bit line including a floating channel region formed on the insulating layer; a tunnel oxide film formed on the floating channel region; a ferroelectric layer formed on the tunnel oxide film, wherein a change in a polarity of the ferroelectric layer induces a change in a resistance of the floating channel region; and a top word line formed on the ferroelectric layer in parallel with the bottom word line.

### BRIEF DESCRIPTION OF THE DRAWINGS

Other aspects and advantages of the present invention will become apparent upon reading the following detailed description and upon reference to the drawings in which:

FIG. 1 is a cross-sectional view illustrating a unit cell of a conventional nonvolatile ferroelectric memory device;

FIGS. 2a and 2b are cross-sectional views illustrating a unit cell of a nonvolatile ferroelectric memory device consistent with the present invention;

FIGS. 3a through 3c and 4a through 4c are diagrams illustrating read and write operations of the unit cell of FIGS. 2a and 2b;

FIG. 5 is a plan view illustrating a nonvolatile ferroelectric memory device consistent with the present invention;

FIG. 6a is a cross-sectional view of the ferroelectric memory device along line A-A′ in FIG. 5;

FIG. 6b is a cross-sectional view of the ferroelectric memory device along line B-B′ in FIG. 5;

FIG. 7 is a cross-sectional view illustrating a nonvolatile ferroelectric memory device having a multi-layer array structure consistent with the present invention;

FIGS. 8a and 8b are cross-sectional views illustrating a unit cell of a nonvolatile ferroelectric memory device consistent with the present invention;

FIGS. 9a, 9b, 10a, and 10b are diagrams illustrating read and write operations of the unit cell of FIGS. 8a and 8b;

FIG. 11 is a plan view illustrating a nonvolatile ferroelectric memory device consistent with the present invention;

FIG. 12a is a cross-sectional view of the ferroelectric memory device along line A-A′ in FIG. 11;

FIG. 12b is a cross-sectional view of the ferroelectric memory device along line B-B′ in FIG. 11; and

FIG. 13 is a cross-sectional view of a nonvolatile ferroelectric memory device having a multi-layer array structure consistent with the present invention.

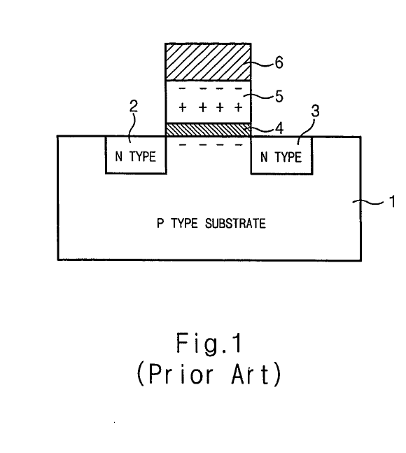

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like part.

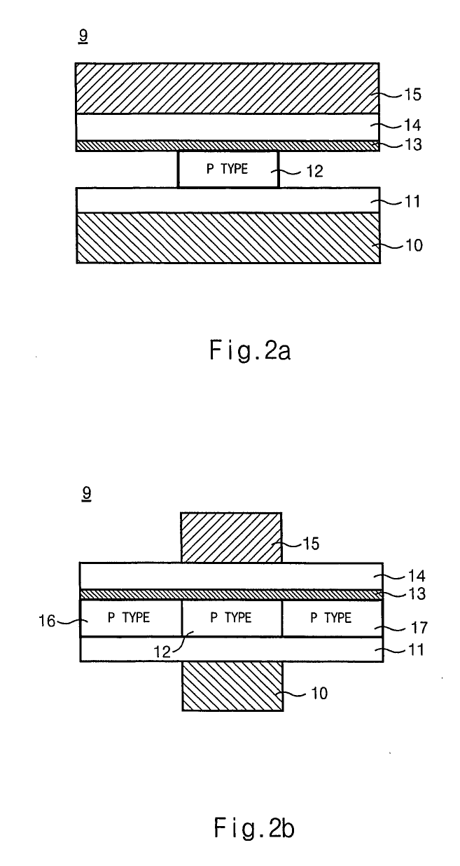

FIGS. 2a and 2b are cross-sectional views illustrating a unit cell 9 of a nonvolatile ferroelectric memory device consistent with the present invention.

FIG. 2a is a cross-sectional view cut in parallel with a top word line.

Referring to FIG. 2a, the unit cell 9 includes a bottom word line 10, an oxide film 11, a bit line including a floating p-type channel region 12, a tunnel oxide 13, a ferroelectric layer 14 and a top word line 15. The bottom word line 10 is arranged in parallel with the top word line 15. Both the bottom word line 10 and the top word line 15 are selectively driven by a row address decoder (not shown).

FIG. 2b is a cross-sectional view cut perpendicular to a top word line. Referring to FIG. 2b, the bit line further includes a p-type drain region 16 and a p-type source region 17 on the sides of the floating p-type channel region 12. The bit line is formed of at least one of a carbon nano tube, a silicon, a germanium, and an organic semiconductor.

Although FIG. 2b shows that the unit cell 9 includes the p-type drain region 16 and the p-type source region 17 on the sides of the p-type channel region 12, the unit cell 9 may alternatively include an n-type drain region and an n-type source region on the sides of an n-type channel region.

Also, although the tunnel oxide film 13 is formed as one layer in the above-described embodiment, the tunnel oxide film 13 may also include a plurality of tunnel oxide films each having different characteristics to improve a connection characteristic between devices in interface regions of the channel region and the ferroelectric layer.

The unit cell 9 reads and writes data by a channel resistance which changes with a polarization state of the ferroelectric layer 14.

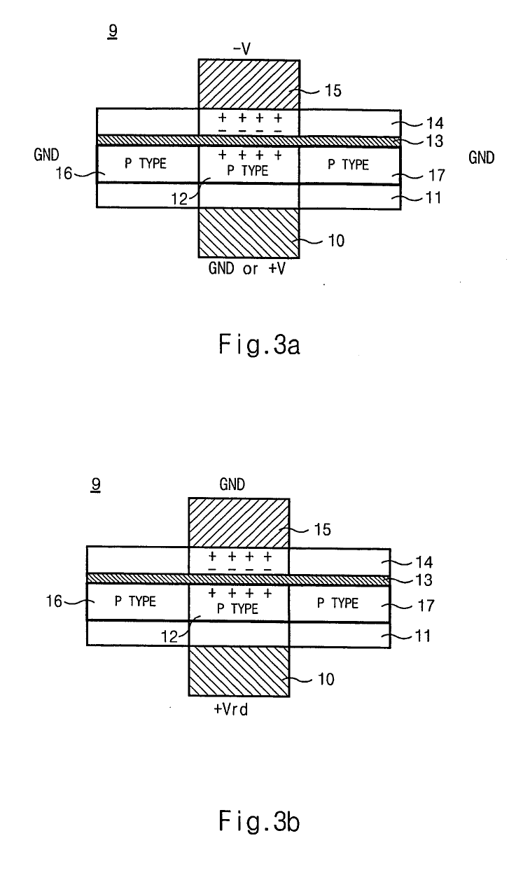

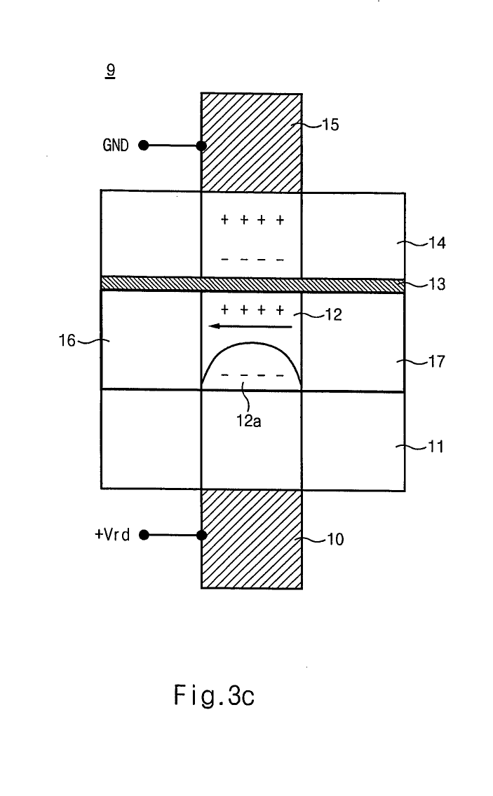

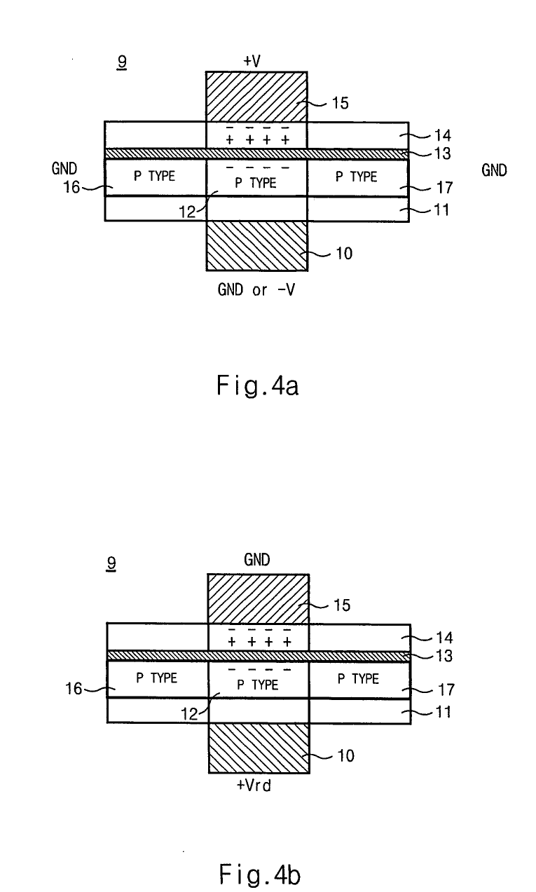

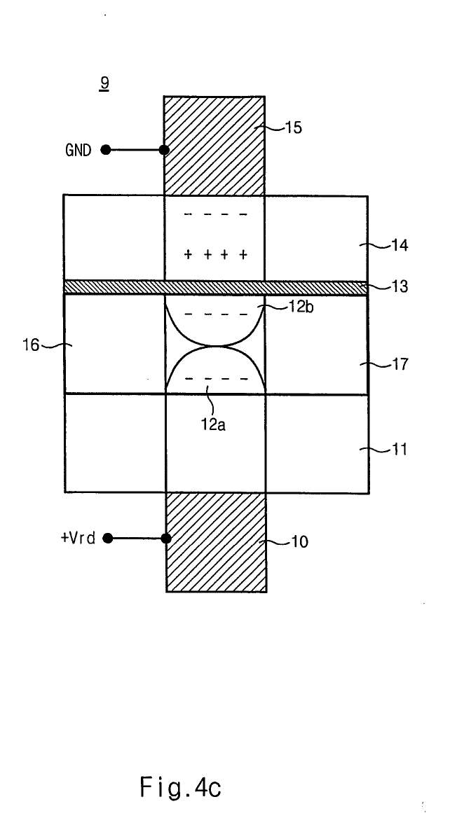

FIGS. 3a-3c and 4a-4c are diagrams illustrating read and write operations of the unit cell 9.

FIG. 3a is a diagram illustrating the operation of writing a bit “1” in the unit cell 9. Referring to FIG. 3a, a ground voltage GND or a positive voltage +V is applied to the bottom word line 10, and a negative voltage −V is applied to the top word line 15. The drain region 16 and the source region 17 are grounded. As a result of the voltages applied to the bottom word line 10, the drain region 16, the source region 17, and the top word line 15, a voltage drop is created between the ferroelectric layer 14 and the p-type channel region 12, such that a polarity of the ferroelectric layer 14 results in positive charges being induced to the top portion of the p-type channel region 12. Consequently, a bit of “1” is stored in the unit cell 9.

FIGS. 3b and 3c are diagrams illustrating the read operation of the unit cell 9 when a bit of “1” is stored in the unit cell 9.

Referring to FIGS. 3b and 3c, when a positive read voltage +Vrd is applied to the bottom word line 10, a depletion layer 12a is formed in the bottom portion of the p-type channel region 12. However, because the top word line 15 is at the ground voltage GND and the polarity of the ferroelectric layer 14 induces positive charges to the p-type channel region 12, the p-type channel region 12 is not fully depleted, and a channel exists in the p-type channel region 12. As a result, a voltage difference between the drain region 16 and the source region 17 will induce a significant amount of current through the p-type channel region 12, from which it may be determined that a bit of “1” is stored in the unit cell 9.

FIG. 4a is a diagram illustrating the operation of writing a bit of “0” in the unit cell 9.

Referring to FIG. 4a, the ground voltage GND or the negative voltage −V is applied to the bottom word line 10, and a positive voltage +V is applied to the top word line 15. The drain region 16 and the source region 17 are grounded.

As a result of the voltages applied to the bottom word line 10, the drain region 16, the source region 17, and the top word line 15, a voltage drop is created between the ferroelectric layer 14 and the p-type channel region 12, such that the polarity of the ferroelectric layer 14 results in negative charges being induced to the top portion of the p-type channel region 12. Consequently, a bit of “0” is stored in the unit cell 9.

FIGS. 4b and 4c are diagrams illustrating the read operation of the unit cell 9 when the unit cell 9 has a bit of “0” stored therein.

Referring to FIGS. 4b and 4c, when the positive read voltage +Vrd is applied to the bottom word line 10, a depletion layer 12a is formed in the bottom portion of the p-type channel region 12. In the mean time, the top word line 15 is grounded. Therefore, a depletion layer 12b is formed in the top portion of the p-type channel region 12 because of the polarity of the ferroelectric layer 14, which induces negative charges to the p-type channel region 12. The depletion layers 12a and 12b effectively block a current path between the drain region 16 and the source region 17. As a result, a voltage difference between the drain region 16 and the source region 17 does not generate a significant current through the p-type channel region 12, from which it may be determined that a bit of “0” is stored in the unit cell 9.

In the unit cell 9 consistent with the present invention, the top word line 15 is at the ground voltage GND in a read mode. As a result, a voltage stress is avoided and the data retention characteristic of the unit cell 9 is improved.

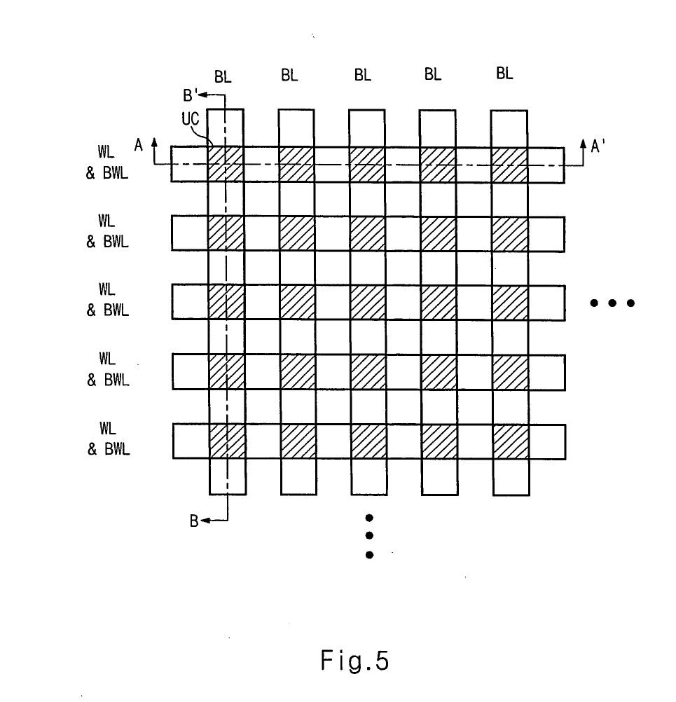

FIG. 5 is a plan view of a nonvolatile ferroelectric memory device consistent with the present invention. Referring to FIG. 5, the ferroelectric memory device includes a plurality of top word lines WL, a plurality of bottom word lines BWL, and a plurality of bit lines BL, the bit lines BL being perpendicular to the top word lines WL and the bottom word lines BWL. Unit cells UC having structures similar to the unit cell 9 shown in FIGS. 2a and 2b are arranged at the cross of the top word lines WL and the bit lines BL.

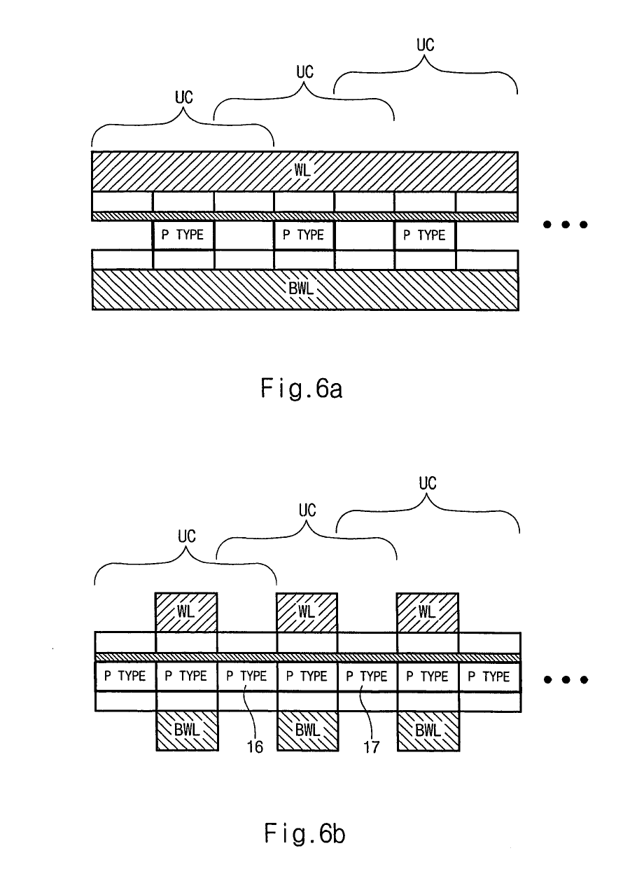

FIG. 6a is a cross-sectional view of the ferroelectric memory device along line A-A′ in FIG. 5. As FIG. 6a shows, the unit cells UC in a row share the same bottom word line BWL and the same top word line WL.

FIG. 6b is a cross-sectional view of the ferroelectric memory device along line B-B′ in FIG. 5. Referring to FIG. 6b, adjacent unit cells UC in a column share the p-type drain region 16 or the p-type source region 17, which are part of the corresponding bit line BL.

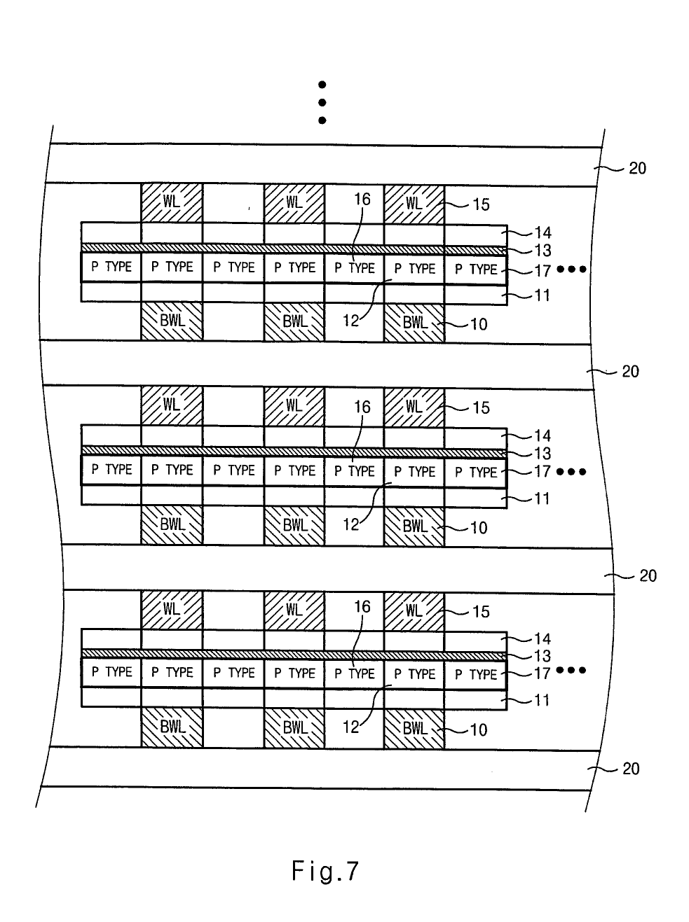

FIG. 7 is a cross-sectional view of a nonvolatile ferroelectric memory device having a multi-layer array structure consistent with the present invention. Referring to FIG. 7, the multi-layer ferroelectric memory device includes a plurality of unit cells arranged in a plurality of layers isolated by a plurality of cell insulating layers 20, each of the unit cells having a structure similar to the unit cell 9 shown in FIGS. 2a and 2b. By arranging the unit cells in layers, the multi-layer ferroelectric memory device achieves a high level of integration.

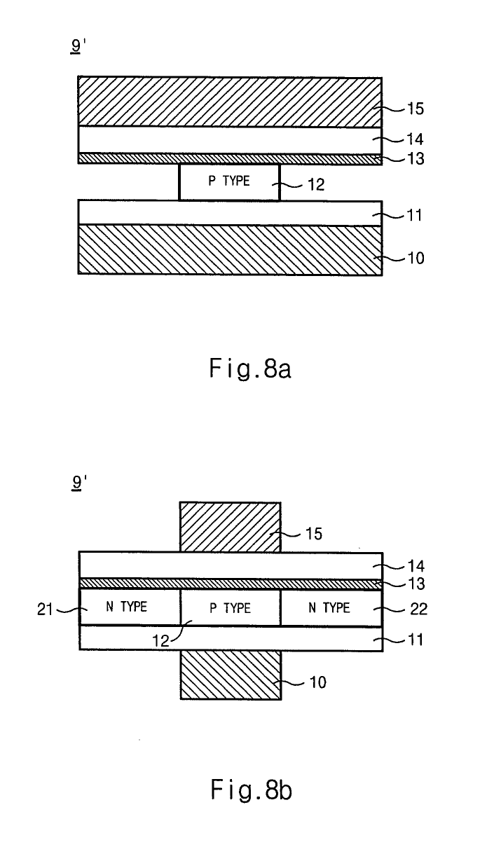

FIGS. 8a and 8b are cross-sectional views illustrating a unit cell 9′ of a nonvolatile ferroelectric memory device consistent with the present invention.

FIG. 8a is a cross-sectional view cut in parallel with a top word line. Referring to FIG. 8a, the unit cell 9′ has a deposited structure including a bottom word line 10, an oxide film 11, a bit line including a floating p-type channel region 12, a tunnel oxide 13, a ferroelectric layer 14 and a top word line 15. The bottom word line 10 is arranged in parallel with the top word line 15. Both the bottom word line 10 and the top word line 15 are selectively driven by a row address decoder (not shown).

FIG. 8b a cross-sectional view cut perpendicular to a top word line. Referring to FIG. 8b, the bit line further includes an n-type drain region 21 and an n-type source region 22 on the sides of the floating p-type channel region 12. The bit line may be formed of at least one of a carbon nano tube, a silicon, a germanium and an organic semiconductor.

Although FIG. 8b shows that the unit cell 9′ includes the n-type drain region 21 and the n-type source region 22 on the sides of the p-type channel region 12 in the above-described embodiment, the unit cell 9′ may alternatively include a p-type drain region and a p-type source region on the sides of an n-type channel region.

Also, although the tunnel oxide film 13 is formed as one layer in the above-described embodiment, the tunnel oxide film 13 may also include a plurality of tunnel oxide films each having different characteristics to improve a connection characteristic between devices in interface regions of the channel region and the ferroelectric layer.

The unit cell 9′ reads and writes data by a channel resistance which changes with a polarization state of the ferroelectric layer 14.

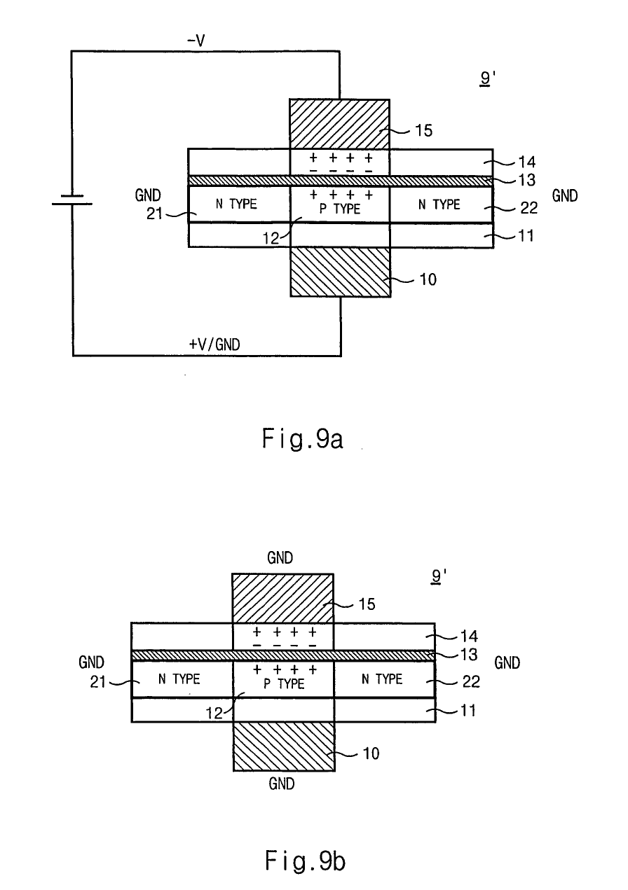

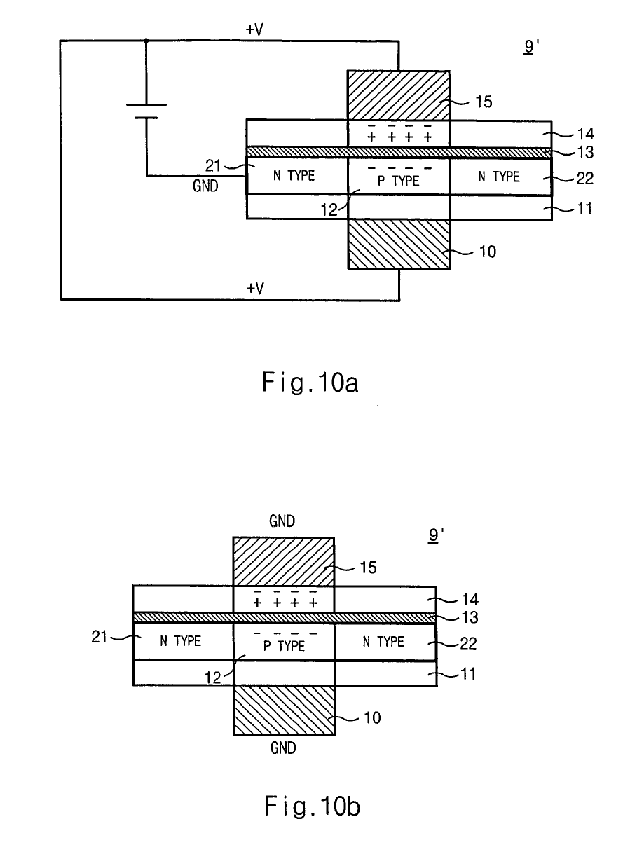

FIGS. 9a, 9b, 10a, and 10b are diagrams illustrating read and write operations of the unit cell 9′.

FIG. 9a is a diagram illustrating the operation of writing a bit of “1” into the unit cell 9′. Referring to FIG. 9a, a ground voltage GND or a positive voltage +V is applied to the bottom word line 10, and a negative voltage −V is applied to the top word line 15. The drain region 21 and the source region 22 are grounded.

As a result of the voltages applied to the bottom word line 10, the drain region 21, the source region 22, and the top word line 15, a voltage drop is created between the ferroelectric layer 14 and the p-type channel region 12 such that the polarity of the ferroelectric layer 14 results in positive charges being induced to the top portion of the p-type channel region 12. Consequently, a bit of “1” is stored in the unit cell 9′.

FIG. 9b is a diagram illustrating the read operation of the unit cell 9′ when the unit cell 9′ has stored therein a bit of “1”. Referring to FIG. 9b, because of the polarity of the ferroelectric layer 14, positive charges are induced to the top of the channel region 12. Also, the bottom word line 10 and the top word line 15 are both grounded. Therefore, no n-type channel is created between the drain region 21 and the source region 22. As a result, a voltage difference between the drain region 21 and the source region 22 does not generate a significant current through the p-type channel region 12, from which it may be determined that a bit of “1” is stored in the unit cell 9′.

FIG. 10a is a diagram illustrating the operation of writing a bit of “0” into the unit cell 9′. Referring to FIG. 10a, a positive voltage +V is applied to the bottom word line 10 and the top word line 15. Here, the drain region 21 is grounded.

As a result of the voltages applied to the bottom word line 10, the drain region 21, the source region 22, and the top word line 15, a voltage drop is created between the ferroelectric layer 14 and the p-type channel region 12 such that the polarity of the ferroelectric layer 14 results in negative charges being induced to the top portion of the p-type channel region 12. Consequently, a bit of “0” is stored in the unit cell 9′.

FIG. 10b is a diagram illustrating the read operation of the unit cell 9′ when the unit cell 9′ has stored therein a bit of “0”. Referring to FIG. 10b, the bottom word line 10 and the top word line 15 are both grounded. Because of the polarity of the ferroelectric layer 14, negative charges are induced to the top of the channel region 12. Therefore, an n-type channel is formed. As a result, a voltage difference between the drain region 21 and the source region 22 generates a significant current through the p-type channel region 12, from which it may be determined that a bit of “0” is stored in the unit cell 9′.

In the unit cell 9′ consistent with the present invention, the top word line 15 and the bottom word line 10 are both grounded in a read mode. As a result, a voltage stress does not exist in ferroelectric layer 14, and the data retention characteristic of the unit cell 9′ is improved.

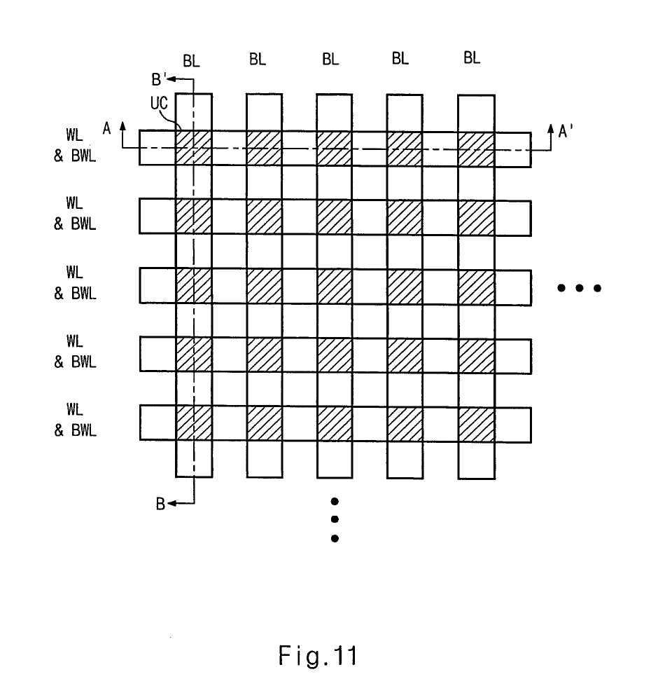

FIG. 11 is a plan view of a nonvolatile ferroelectric memory device consistent with the present invention. Referring to FIG. 11, the ferroelectric memory device includes a plurality of top word lines WL, a plurality of bottom word lines BWL, and a plurality of bit lines BL, the bit lines BL being perpendicular to the top word lines WL and the bottom word lines BWL. Unit cells UC having structures similar to the unit cell 9′ shown in FIGS. 8a and 8b are arranged at the cross of the top word lines WL and the bit lines BL.

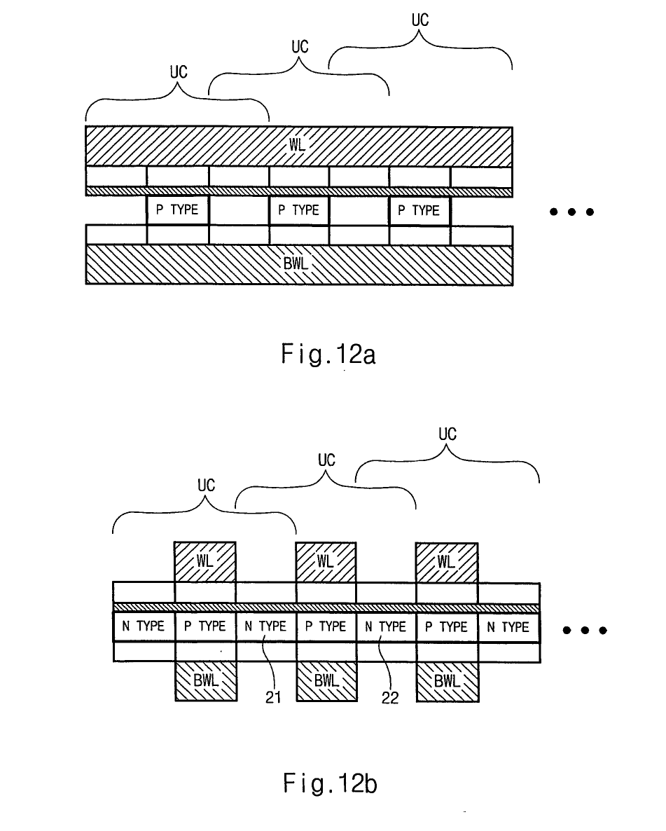

FIG. 12a is a cross-sectional view of the ferroelectric memory device along line A-A′ in FIG. 11. Referring to FIG. 12a, unit cells UC in a row share the same bottom word line BWL and the same top word line WL.

FIG. 12b is a cross-sectional view of the ferroelectric memory device along B-B′ in FIG. 11. Referring to FIG. 12b, adjacent unit cells UC in a column share the n-type drain region 21 or the n-type source region 22, which are part of the corresponding bit line BL.

The n-type drain region 21 can be used as a source region in the adjacent cell, and the n-type source region 22 can be used as a drain region in the adjacent cell. That is, the n-type region 21 or 22 is used in common as a drain region and a source region in the adjacent cell.

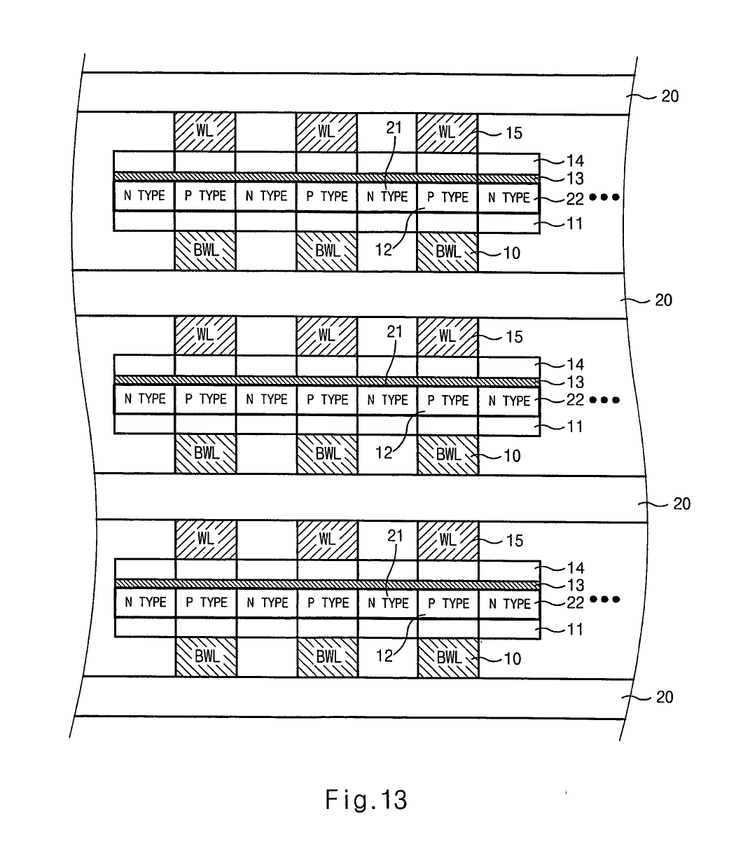

FIG. 13 is a cross-sectional view of a nonvolatile ferroelectric memory device having a multi-layer array structure consistent with the present invention.

Referring to FIG. 13, the multi-layer ferroelectric memory device includes a plurality of unit cells arranged in a plurality of layers isolated by a plurality of insulating layers 20, each of the unit cells having a structure similar to the unit cell 9′ shown in FIGS. 8a and 8b. By arranging the unit cells in layers, the multi-layer ferroelectric memory device achieves a high level of integration.

As described above, in a nonvolatile ferroelectric memory device consistent with the present invention, an NDRO (Non Destructive Read Out) mechanism prevents cell data from being destroyed in a read mode. Reliability and an operation speed of the nonvolatile ferroelectric memory device are improved. Also, a plurality of ferroelectric unit cell arrays are arranged in multiple layers to improve the integration capacity of cells, thereby reducing the whole size of cells. In the nonvolatile ferroelectric memory device, a tunnel oxide film is formed between a floating channel layer and a ferroelectric layer to prevent diffusion of impurities of the ferroelectric layer. Furthermore, all depolarization charges between the ferroelectric layer and the oxide film are emitted through the tunnel oxide film to improve the retention characteristic of the ferroelectric layer.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A nonvolatile ferroelectric memory device comprising:
a bottom word line;
an insulating layer formed on the bottom word line;
a bit line including a floating channel region formed on the insulating layer;
a tunnel oxide film formed on the floating channel region;
a ferroelectric layer formed on the tunnel oxide film, wherein a change in a polarity of the ferroelectric layer induces a change in a resistance of the floating channel region; and
a top word line formed on the ferroelectric layer in parallel with the bottom word line.

2. The nonvolatile ferroelectric memory device according to claim 1, wherein the bit line comprises one of a carbon nano tube, a silicon, a germanium and an organic semiconductor.

3. The nonvolatile ferroelectric memory device according to claim 1, wherein the floating channel region comprises an n-type channel region having two sides, and the bit line further comprises a p-type drain region and a p-type source region on the sides of the n-type channel region.

4. The nonvolatile ferroelectric memory device according to claim 3, wherein the n-type channel region has a first resistance when positive charges are induced therein by a first polarization of the ferroelectric layer and has a second resistance when negative charges are induced therein by a second polarization of the ferroelectric layer, the first resistance being lower than the second resistance.

5. The nonvolatile ferroelectric memory device according to claim 1, wherein the floating channel region comprises a p-type channel region having two sides, and the bit line further comprises an n-type drain region and an n-type source on the sides of the p-type channel region.

6. The nonvolatile ferroelectric memory device according to claim 5, wherein the p-type channel region has a first resistance when positive charges are induced therein by a first polarization of the ferroelectric layer and has a second resistance when negative charges are induced therein by a second polarization of the ferroelectric layer, the first resistance being lower than the second resistance.

7. The nonvolatile ferroelectric memory device according to claim 1, wherein the floating channel region comprises a p-type channel region having two sides, and the bit line further comprises a p-type drain region and a p-type source region on the sides of the p-type channel region.

8. The nonvolatile ferroelectric memory device according to claim 7, wherein the p-type channel region has a first resistance when positive charges are induced therein by a first polarization of the ferroelectric layer and has a second resistance when negative charges are induced therein by a second polarization of the ferroelectric layer, the first resistance being lower than the second resistance.

9. The nonvolatile ferroelectric memory device according to claim 1, wherein the floating channel comprises an n-type channel region having two sides, and the bit line further comprises an n-type drain region and an n-type source region on the sides of the channel region.

10. The nonvolatile ferroelectric memory device according to claim 9, wherein the n-type channel region has a first resistance when positive charges are induced therein by a first polarization of the ferroelectric layer, and has a second resistance when negative charges are induced therein by a second polarization of the ferroelectric layer, the first resistance being lower than the second resistance.

11. The nonvolatile ferroelectric memory device according to claim 1, wherein the tunnel oxide film comprises a plurality of oxide films.

12. A nonvolatile ferroelectric memory device including a plurality of unit cells arranged in a plurality of layers, wherein each of the unit cells comprises:
a bottom word line;
an insulating layer formed on the bottom word line;
a bit line including a floating channel region formed on the insulating layer;
a tunnel oxide film formed on the floating channel region;
a ferroelectric layer formed on the tunnel oxide film, wherein a change in a polarity of the ferroelectric layer induces a change in a resistance of the floating channel region; and
a top word line formed on the ferroelectric layer in parallel with the bottom word line.

13. The nonvolatile ferroelectric memory device according to claim 12, wherein the plurality of layers are separated from each other by a cell insulating layer.

14. The nonvolatile ferroelectric memory device according to claim 12, wherein the bit line comprises one of a carbon nano tube, a silicon and a germanium.

15. The nonvolatile ferroelectric memory device according to claim 12, wherein the tunnel oxide film includes a plurality of oxide films.
